(19) United States
(12) Patent Application Publication
(10) Pub. No.: US 2009/0302337 A1
(43) Pub. Date: Dec. 10, 2009

(54) LIGHT EMITTING DIODE SYSTEM

(75) Inventor: CHIA-SHOU CHANG, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: FOXCONN TECHNOLOGY CO., LTD., Tu-Cheng (TW)

(21) Appl. No.: 12/185,124

(22) Filed: Aug. 4, 2008

(30) Foreign Application Priority Data
Jun. 6, 2008 (CN) 200810067672.9

(51) Int. Cl. H01L 33/00

(52) U.S. Cl. 257/98; 257/E33.001

(57) ABSTRACT

An exemplary light emitting diode (LED) structure includes a base, a plurality of LED chips and an encapsulation material. The base defines a plurality of first channels located adjacent to a top surface thereof and a plurality of second channels located adjacent to a bottom surface thereof. Each of the first and the second channels extends along a vertical axis of the base. A projection of the first channels on the bottom surface of the base does not overlap with the projection of the second channels on the bottom surface of the base. The projection of the second channels on the bottom surface of the base is closer to the projection of one corresponding LED chip on the bottom surface of the base with respect to the projection of the first channels. A plurality of heat dissipation poles are filled in the first and the second channels.

### BACKGROUND

1. Technical Field

The present invention relates to light emitting diodes, and more specifically to a light emitting diode system.

2. Description of Related Art

Presently, LEDs (light emitting diode) are preferred for use in non-emissive display devices rather than CCFLs (cold cathode fluorescent lamp) due to high brightness, long lifespan, and wide color range.

Referring to FIG. 7, a LED system includes a substrate 10, a plurality of LED chips 12 disposed on the substrate 10 and an encapsulation material 14 encapsulating the LED chips 12 on the substrate 10. Each of the LED chips 12 is electrically connected to the substrate 10 via a gold wire 13. The substrate 10 is a flat plate of materials having thermal conductivities. Heat generated by the LED chips 12 is dissipated into a surrounding environment of the LED system via the substrate 10.

However, the LED chip 12 is intended to be more powerful while maintaining a smaller size. Hot spots are formed between each of the LED chips 12 and the substrate 10, and heat generated at the hot spots needs to be transferred to other areas of the substrate 10 and further dissipated to the surrounding environment. The substrate 10 has low heat transfer efficiency due to its flat shape restriction and simplex material restriction. Therefore, the heat in the hot spots can not be timely dissipated and the hot spots have a high temperature.

For the foregoing reasons, it is desirable to provide a LED system which can overcome the described limitations.

### SUMMARY

A light emitting diode system is provided. According to an exemplary embodiment, the light emitting diode system includes a base, at least one light emitting diode chip, a plurality of heat dissipation poles and an encapsulation material. The base defines a plurality of first channels and at least one second channel therein. Each of the first channels and the at least one second channel extends along a vertical axis of the base. The first channels are located adjacent to a top surface of the base. The at least one second channel is located adjacent to a bottom surface of the base. A projection of the first channels on the bottom surface of the base does not overlap with the projection of at least one second channel on the bottom surface of the base. The at least one light emitting diode chip is mounted on the top surface of the base. The projection of the at least one second channel on the bottom surface of the base is aligned with the projection of the at least one light emitting diode chip on the bottom surface of the base. The projection of the first channels surrounds the projection of the at least one light emitting diode chip. The heat dissipation poles are filled in the first channels and the at least one second channel. The encapsulation material is disposed on the top surface of the base and encapsulates the at least one light emitting diode chip therein.

Other advantages and novel features of the present invention will become more apparent from the following detailed description of embodiment when taken in conjunction with the accompanying drawings.

### BRIEF DESCRIPTION OF THE DRAWINGS

FIG. 1 is a schematic, top plan view of a light emitting diode system in accordance with a first exemplary embodiment of the present invention.

FIG. 2 is a cross-section of the light emitting diode system of FIG. 1, taken along line 11-11 thereof.

FIG. 3 is a schematic, top plan view of a light emitting diode system in accordance with a second exemplary embodiment of the present invention.

FIG. 4 is a cross-section of the light emitting diode system of FIG. 3, taken along line IV-IV thereof.

FIG. 5 is a schematic, top plan view of a light emitting diode system in accordance with a third exemplary embodiment of the present invention.

FIG. 6 is a cross-section of the light emitting diode system of FIG. 5, taken along line VI-VI thereof.

FIG. 7 is a schematic view of a light emitting diode system according to related technology.

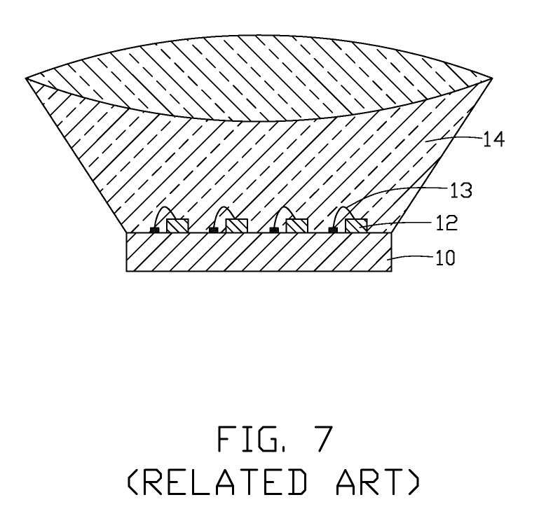

### DETAILED DESCRIPTION OF THE EMBODIMENTS

Reference will now be made to the drawings to describe the various present embodiments in detail.

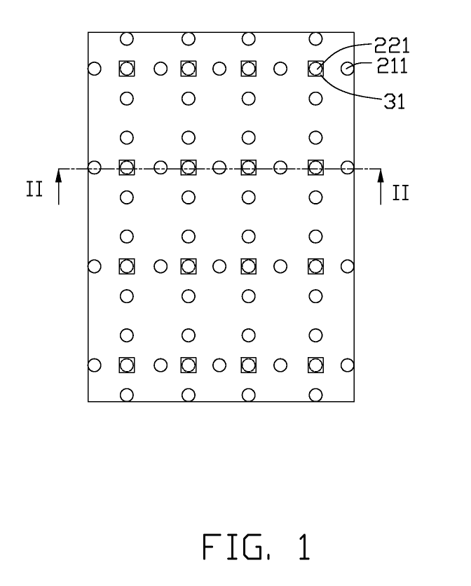

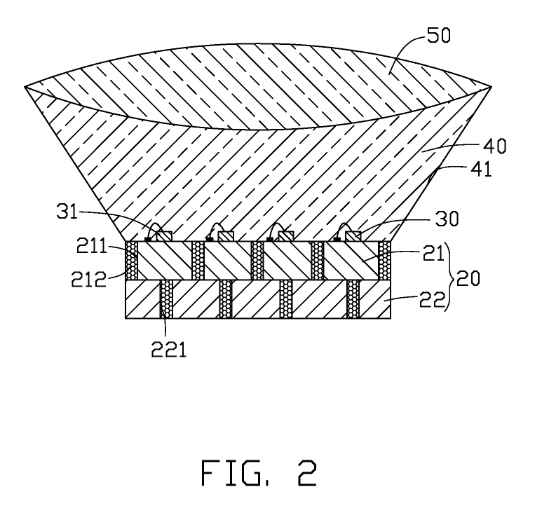

Referring to FIGS. 1 and 2, a light emitting diode (LED) structure includes a base 20, a LED array 30 disposed thereon, an encapsulation material 40 on the base 20 protecting the LED array 30, and a lens 50 on the encapsulation material 40.

The LED array 30 includes a plurality of LED chips 31 arranged in a matrix. The LED array 30 includes four lines of LED chips 31 and four rows of LED chips 31. Each of the LED chips 31 is rectangular, and electrically connects with an electrical layer (not shown) of the base 20. The base 20 electrically connects with an external power supply (not shown), electrically connecting each of the LED chips 31 with the power supply.

The base 20 is of materials having high thermal conductivity. In this embodiment, the base 20 is metal such as aluminum, or copper. Alternatively, the base 20 can be ceramic.

The base 20 includes an upper substrate 21 and a lower substrate 22 fixed to a bottom surface of the upper substrate 21. A plurality of square first channel assemblies is defined in the upper substrate 21. The LED chips 31 are mounted on a top surface of the upper substrate 21. The first channel assemblies correspond to the LED chips 31, respectively. Each of the first channel assemblies includes four first channels 211 surrounding a corresponding LED chip 31. As shown in FIG. 1, the four first channels 211 of each of the first channel assemblies are respectively located at a front side, a rear side, a left side and a right side of the corresponding LED chip 31 symmetrically, wherein only two first channels 211 of the first channel assembly are visible in FIG. 2. Each of the first channels 211 runs through the upper substrate 21 along a vertical axis of the upper substrate 21. That is, each of the first channels 211 extends from the top surface of the upper substrate 21 towards the bottom surface thereof.

A top surface of the lower substrate 22 is affixed to the bottom surface of the upper substrate 21. The lower substrate 22 is thermally attached to the upper substrate 21, preferably with a thermal interface material (not shown) applied therebetween to enhance heat transfer efficiency. A plurality of second channel assemblies is defined in the lower substrate 22. The second channel assemblies correspond to the LED chips 31, respectively. Each of the second channel assemblies includes one second channel 221 just under the corresponding LED chip 31 and the first channels 211 of the first channel assembly symmetrically surround a corresponding second channel 221. Each of the second channels 221 runs through the lower substrate 22 along the vertical axis of the lower substrate 22. The second channels 221 and the first channels 211 are staggered, as shown in FIG. 2, and the second channels 221 of the lower substrate 22 do not communicate with the first channels 211 of the upper substrate 21 along the vertical axis of the base 20. A projection of the first channels 211 of each first channel assembly on a bottom surface of the base 20 is around the projection of the corresponding LED chip 31 on the bottom surface of the base 20. The projection of the second channel 221 of each second channel assembly on the bottom surface of the base 20 overlaps the projection of the corresponding LED chip 31 on the bottom surface of the base 20.

A plurality of heat dissipation poles 212 is filled in the first channels 211 of the upper substrate 21 and the second channels 221 of the lower substrate 22. Each of the heat dissipation poles 212 is of material having high thermal conductivity, and defines a plurality of pores communicating with each other. In this embodiment, each of the heat dissipation poles 212 is a metal foam column, of the same metal material as the upper substrate 21 and the lower substrate 22 of the base 20. Alternatively, the heat dissipation poles 212 can be other porous materials with high thermal conductivity. For example, from sintered metal powders such as copper, ceramic, or others.

The encapsulation material 40 is light permeable material, such as glass, epoxy, resin, or other. The encapsulation material 40 is located on the top surface of the upper substrate 21 and mounted around the LED array 30 for encapsulating the LED chips 31 therein. The encapsulation material 40 is substantially an inverted frustum, a cross section of which includes two lateral sides 41 inclined with respect to the top surface of the upper substrate 21. The encapsulation material 40 includes a concave top surface (not labeled) supporting the lens 50. Diameter of the encapsulation material 40 gradually increases from a bottom end of the encapsulation material 40 towards a top end thereof.

The lens 50 is transparent, light permeable material, such as epoxy resin, glass or other. In this embodiment, the lens 50 is glass, providing the lens with resistance to high temperature, erosion, scratches and other damage. The lens 50 is bi-convex, having a convex bottom surface matching the concave top surface of the encapsulation material 40, and a convex top surface in the face of a surrounding environment of the LED system. The convex bottom surface of the lens 50 is affixed to the concave top surface of encapsulation material 40. The lens 50 has a positive refracting power for converging light emitted from the LED chips 31.

During operation, the LED chips 31 generate heat. Since the LED chips 31 are thermally connected with the upper substrate 21, the heat generated by the LED chips 31 is firstly gathered in contacting areas, which are formed between each of the LED chips 31 and the upper substrate 21 respectively. The heat in the contacting areas is further conducted to other portions of the upper substrate 21 along a horizontal axis of the base 20, and to the lower substrate 22 along a vertical axis of the base 20, simultaneously. For the first channels 211 located adjacent to the LED chips 31 and the heat dissipation poles 212 filled in the first channels 211, the heat is conductable to the first channels 211 and further to the lower substrate 22 through the heat dissipation poles 212 quickly, which improves heat conduction of the upper substrate 21 along the vertical axis thereof and thus improves the heat conducting efficiency between the top surface of the upper substrate 21 and the bottom surface thereof.

In addition, the lower substrate 22 intimately contacts the bottom surface of the upper substrate 21 and has functions similar to the upper substrate 21. More specifically, the heat dissipation poles 212 of the lower substrate 22 are located just under the contacting areas of the upper substrate 21, and heat at the contact areas can be conducted to the heat dissipation poles 212 of the lower substrate 22 directly, further to be dissipated into the surrounding environment through the heat dissipation poles 212. Moreover, the second channels 221 of the lower substrate 22 and the first channels 211 of the upper substrate 21 are staggered, with heat conducted to the lower substrate 22 by the heat dissipation poles 212 of the upper substrate 21 able to be uniformly distributed over the lower substrate 22 and further dissipated to the surrounding environment, increasing heat dissipation efficiency of the base 20. Thus, heat generated by the LED chips 31 can be quickly transferred to other portions of the base 20 and heat dissipation effectiveness of this LED system is enhanced.

Alternatively, the upper substrate 21 and the lower substrate 22 of the base 20 can be integrally formed as a single piece. In this condition, the first channels 211 extending along the vertical axis of the upper substrate 21 are defined in a top portion of the base, and the second channels 221 extending along the vertical axis of the lower substrate 22 are defined in a bottom portion of the base. The first channels 211 and the second channels 221 are staggered, and top ends of the second channels 221 and bottom ends of the first channels 211 are at the same level. Understandably, the top ends of the second channels 221 can be higher than the bottom ends of the first channels 211, or the top ends of the second channels 221 can be lower than the bottom ends of the first channels 211 according to different requirements.

Alternatively, layout of the first channels 211 and the second channels 221 in the base 20 also can be varied. An only requirement is that the projection of the first channels 211 on the bottom surface of the base 20 has no overlapping portion with the projection of the second channels 221 on the bottom surface of the base 20, and the projection of the second channels 221 of each second channel assembly is closer to the projection of the corresponding LED chip 31 on the bottom surface of the base 20 than the projection of the first channels 211 of each first channel assemblies.

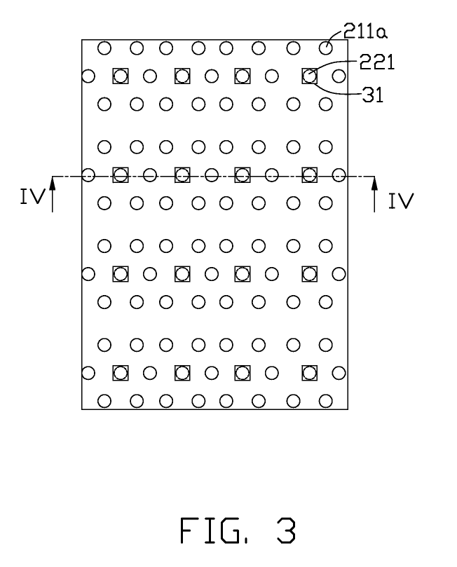

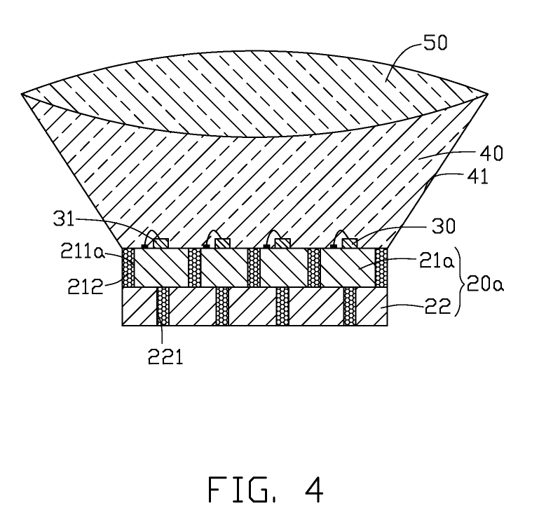

FIG. 3 and FIG. 4 show a second embodiment of the LED system. The difference between the second embodiment and the previous first embodiment is: each of the first channel assemblies defined in the upper substrate 21a of the base 20a is substantially a regular hexagon shape and includes six first channels 211a surrounding the corresponding LED chip 31. The six first channels 211a are evenly and separately distributed along an outer periphery of the corresponding LED chip 31, thereby enclosing the corresponding LED chip 31 in a centre thereof.

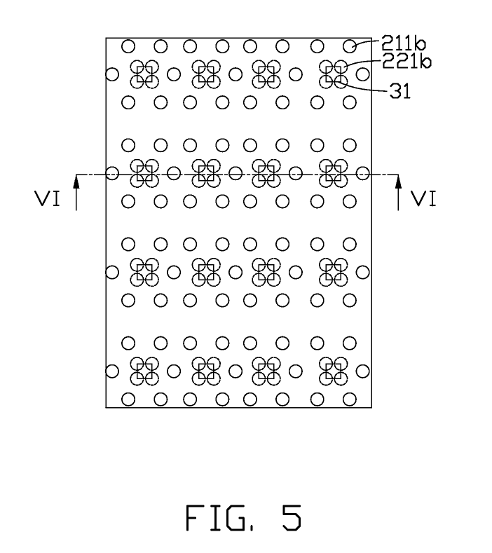

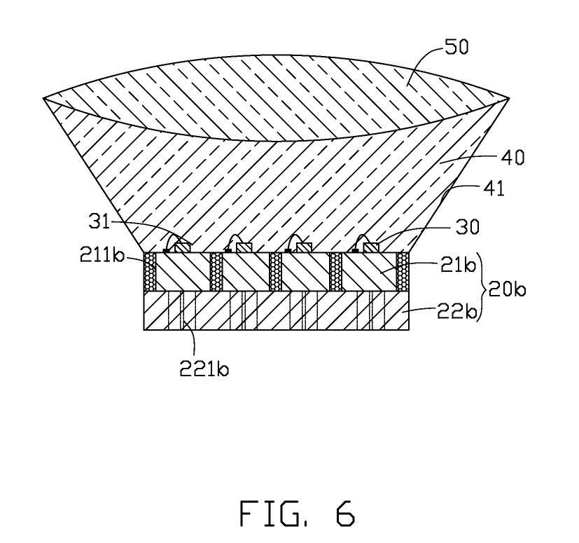

FIG. 5 and FIG. 6 show a third embodiment of the LED system. The difference between the third embodiment and the previous second embodiment is that each of the second channel assemblies defined in the lower substrate 22b of the base 20b is substantially square and includes four second channels 221b close to each other and located under the corresponding LED chip 31. In this embodiment, the four second channels 221b of each second channel assembly are located on four vertices of the corresponding LED chip 31, and enclosed by the first channels 211b of a corresponding first channel assembly. The projection of the second channels 221b on the bottom surface of the base 20b overlaps a portion of the projection of the corresponding LED chip 31 on the bottom surface of the base 20b.

It is to be understood, however, that even though numerous characteristics and advantages of the present invention have been set forth in the foregoing description, together with details of the structure and function of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A light emitting diode system comprising:
a base defining a plurality of first channels and at least one second channel therein, each of the first channels and the at least one second channel extending along a vertical axis of the base, the first channels located adjacent a top surface of the base, the at least one second channel located adjacent to a bottom surface of the base, a projection of the first channels on the bottom surface of the base having no overlapping portion with the projection of at least one second channel on the bottom surface of the base;
at least one light emitting diode chip mounted on the top surface of the base, wherein the projection of the at least one second channel on the bottom surface of the base is closer to the projection of the at least one light emitting diode chip on the bottom surface of the base than the projection of the first channels on the bottom surface of the base;
a plurality of heat dissipation poles filled in the first channels and the at least one second channel; and
an encapsulation material disposed on the top surface of the base and encapsulating the at least one light emitting diode chip therein.

2. The light emitting diode system of claim 1, wherein the projection of the first channels on the bottom surface of the base surrounds the projection of the at least one light emitting diode chip on the bottom surface of the base, and the projection of the at least one second channel on the bottom surface of the base overlaps the projection of the at least one light emitting diode chip on the bottom surface of the base.

3. The light emitting diode system of claim 2, wherein the first channels comprise four first channels surrounding the at least one light emitting diode chip and are square shape, and the at least one second channel is just under the light emitting diode chip.

4. The light emitting diode system of claim 2, wherein the first channels comprise six first channels surrounding the at least one light emitting diode chip and are regularly hexagonal, and the at least one second channel is just under the light emitting diode chip.

5. The light emitting diode system of claim 1, wherein the projection of the first channels on the bottom surface of the base surrounds the projection of the at least one light emitting diode chip on the bottom surface of the base, the at least one second channel comprises a plurality in number, and the projection of the second channels overlaps a portion of the projection of the at least one light emitting diode chip on the bottom surface of the base.

6. The light emitting diode system of claim 5, wherein the first channels comprise six first channels surrounding the at least one light emitting diode chip and are regularly hexagonal, the second channels comprise four second channels close to each other, are under the at least one light emitting diode chip, and are square.

7. The light emitting diode system of claim 1, wherein the first channels are on an upper half portion of the base, and the at least one second channel is on a lower half portion of the base.

8. The light emitting diode system of claim 1, wherein the base comprises an upper substrate and a lower substrate intimately contacting a bottom surface of the upper substrate, the first channels are defined in the upper substrate, and the at least one second channel is defined in the lower substrate.

9. The light emitting diode system of claim 8, wherein each of the first channels runs through the upper substrate, and the at least one second channel runs through the lower substrate.

10. The light emitting diode system of claim 1, wherein each of the heat dissipation poles defines a plurality of pores communicating with each other.

11. The light emitting diode system of claim 10, wherein each of the heat dissipation poles is a metal foam column.

12. The light emitting diode system of claim 11, wherein each of the heat dissipation poles is made of sintered metal powders.

13. The light emitting diode system of claim 1, further comprising a lens above the encapsulation material, the lens having a positive refracting power for converging light emitted from the at least one light emitting diode chip.
